(19) United States
(12) Patent Application Publication
(10) Pub. No.: US 2007/0048451 A1
(43) Pub. Date: Mar. 1, 2007

(54) Substrate movement and process chamber scheduling

(75) Inventors: John White, Hayward, CA (US); Takako Takehara, Hayward, CA (US); Inchen Huang, Fremont, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/213,349

(22) Filed: Aug. 26, 2005

(51) Int. Cl. B05D 1/36; C23C 28/00; B05D 5/12; C23C 16/00

(52) U.S. Cl. 427/402; 427/124; 427/123; 427/96.8; 427/250; 427/255.15; 427/255.7; 427/404

(57) ABSTRACT

A method for depositing tree or more layers on two or more substrates using various chambers in a substrate processing system is provided. In addition, the invention provides substrate transfer methods and suitable substrate processing systems to maximize the throughput of the substrate processing systems and minimizing system footprint. The movements of a transfer robot in the substrate processing system are specifically configured for scheduling two or more process chambers in order to transfer multiple substrates and exchange the substrates between two chambers of the substrate processing system.

### BACKGROUND OF THE INVENTION

1. Field of the Invention

Embodiments of the present invention generally relate to substrate processing systems having process chambers and robots therein.

2. Description of the Related Art

Fabrication of semiconductor integrated circuits (IC) and flat panel display (FPD) devices require processing of multilayer film stacks to create devices, conductors and insulators on a substrate. In general, the substrate for device fabrication is subjected to various processes, such as sputtering, chemical vapor deposition (CVD), physical vapor deposition (PVD), lithography, etching, ion implantation, ashing, cleaning, heating, annealing, and the like repeated multiple times in a specific multi-step fabrication sequence to process layers of metal and silicon containing films thereon. Typically, a process chamber can be configured to deposit a single layer on a substrate. In addition, a number of process chambers may be coupled together to a central transfer chamber for multi-substrate processing in a multi-substrate processing platform, such as a cluster tool, examples of which are the families of AKT PECVD, PRODUCER®, CENTURA® and ENDURA® processing platforms available from Applied Materials, Inc., of Santa Clara, Calif.

Physical vapor deposition (PVD), or sputtering, is one of the most commonly used processes in devices fabrication. PVD is a plasma process performed in a vacuum process chamber where a negatively biased target with respect to a chamber body or a grounded sputter shield is exposed to a plasma of a gas mixture. Bombardment of the target by ions of the gas mixture results in ejection of atoms of the target material. In some case, a magnetron is positioned in the back of the target to project a magnetic field parallel to the front side of the target to trap electrons and increase plasma density and sputtering rate. The ejected atoms accumulate as a deposited film on a substrate placed on a substrate pedestal disposed within the process chamber.

As the demand for semiconductor and flat panel devices continues to grow, there is a trend to reduce cost by increasing the sizes of the substrates for large scale fabrication. For example, glass substrates utilized for flat panel fabrication, such as computer monitors, large screen televisions, displays for personal digital assistants, and cell phones, as well as solar cells, and the like, have increased in size from 550 mm×650 mm to 1500 mm×1800 mm in just a few years and are envisioned to exceed four square meters in the near future.

Thus, the dimension of a process chamber or a multi-substrate processing platform has become very large. It is necessary to reduce the manufacturing cost by reducing the footprint of the substrate processing system and/or increasing the throughput of the substrate processing system, especially for processing multiple substrates having multilayer film stacks thereon. This is especially troublesome for depositing two or more layers on the substrates when two or more substrates need to be processed one after another using two or more process chambers and additional substrate heating and cooling before and after substrate processing may also need to be performed on each of the substrates. As a result, low throughput, processing bottleneck step, or dead lock may often be observed without proper process chamber scheduling and optimized substrate transfer timing. It is desirable to design a substrate processing system using the minimum required hardware to accommodate sequential deposition of two or more layers on two or more substrates in an optimized timely manner with greatly increased throughput and reduced costs.

Therefore, there is a need for an improved method and apparatus to deposit multilayer thin films on a substrate.

### SUMMARY OF THE INVENTION

The present invention generally provides a substrate processing system and a method for scheduling two or more process chambers and transferring two or more substrates in the substrate processing system. In one embodiment, the method includes.

In another embodiment, a method of includes.

In still another embodiment, a method of.

Also provided is a method of transferring two or more substrate in a substrate processing system. The method includes.

In another embodiment, a method.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow diagram of an exemplary method for in-situ processing of a film stack according to one embodiment of the invention.

FIG. 2 is a plan view of an exemplary cluster tool configured for in-situ processing of a film stack according to one embodiment of the invention.

FIG. 3 is a plan view of an exemplary transfer chamber having an exemplary transfer robot configured for high throughput substrate transfer according to one embodiment of the invention.

FIG. 4 depicts a flow diagram of an exemplary method for process chamber scheduling using an exemplary cluster tool according to one embodiment of the invention.

FIG. 5 is a flow diagram of an exemplary method for substrate transfer and exchange between process chambers according to one embodiment of the invention.

FIG. 6A is a plan view of an exemplary cluster tool configured for in-situ processing of a film stack according to one embodiment of the invention.

FIG. 6B is a plan view of an exemplary cluster tool configured for in-situ processing of a film stack according to another embodiment of the invention.

FIG. 6B is a plan view of an exemplary cluster tool configured for in-situ processing of a film stack according to still another embodiment of the invention.

FIG. 7 is a cross-sectional view of one embodiment of an exemplary substrate loading and unloading station configured for substrate heating and cooling.

### DETAILED DESCRIPTION

The invention provides methods for substrate transfer, substrate exchange, and process chamber scheduling within a cluster tool configured for multi-substrate processing. Substrate transfer and substrate exchange timing are optimized and minimum number of process chambers are utilized and scheduled for in-situ processing of a film stack containing a plurality of metal-containing layers on a number of large area substrates, resulting in high throughput multi-substrate processing. In one embodiment, the substrate processing system may include a minimum of two PVD chambers designated to sequentially deposit three or more metal materials in-situ on the substrates by exposing to gas-phase materials or plasma.

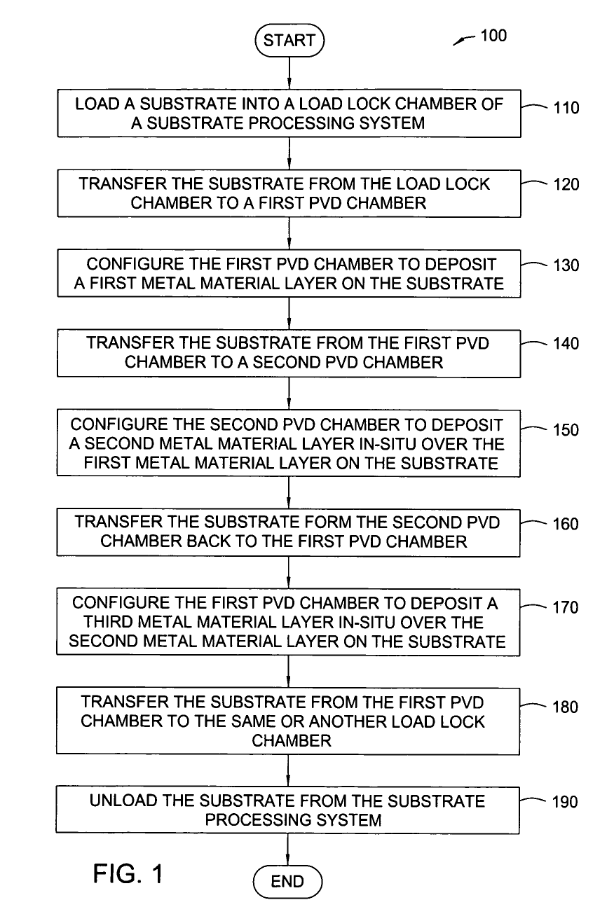

FIG. 1 illustrates a flow chart of a method 100 for in-situ processing of a film stack on an exemplary substrate according to one or more embodiments of the invention. At step 110, a cluster-type substrate processing system having at least a first PVD chamber and a second PVD chamber is provided and a substrate is loaded onto a load-lock chamber of the substrate processing system. In one embodiment, the load lock chamber can be configured to pre-heat the substrate to a processing temperature in order to reduce total process time.

At step 120, the substrate is transferred by a transfer robot from the load-lock chamber of the substrate processing system to the first PVD chamber. At step 130, the first PVD chamber is configured to deposit a first metal material layer on the substrate. At step 140, the substrate is transferred from the first PVD chamber to the second PVD chamber. At step 150, the second PVD chamber is configured to deposit a second metal material layer in-situ over the first metal material layer without breaking vacuum or any surface treatment on the surface of the substrate.

At step 160, the substrate is transferred by the transfer robot back to the first PVD chamber. At step 170, a third metal material layer is deposited in-situ over the surface of the second material layer using the first PVD chamber. Thus, a minimum of two PVD chamber can be used to deposit three metal material layers on the substrates. In one embodiment, the third metal material layer and the first metal material layer comprises the same metal material and there is no need to change the target material of the first PVD chamber.

At step 180, the substrate is transferred by the transfer robot from the second PVD chamber to a load lock chamber, which may be the same load lock chamber for loading the substrate or a different load lock chamber, slot, or compartment. In one embodiment, the load lock chamber is configured to cool the substrate. At step 190, the substrate is unloaded from the load lock chamber of the substrate processing system. Accordingly, the film stack having at least the first metal material layer, the second metal material layer, and the third metal material layer is deposited over the substrate using the first PVD chamber and the second PVD chamber. In another embodiment, the substrate processing system is also configured to include other types of process chambers to perform additional etching, deposition, annealing, and cleaning processes.

In addition, one or more surface treatments can be performed prior to deposition of the film stack of the invention or after deposition of the film stack on the surface of the substrate. For example, the substrate may be heated by using a radiant heat lamp, inductive heater, or an IR type resistive heater, and/or annealed in an annealing chamber. As another example, the substrate may be chemically cleaned prior to or the steps of the method 100 using any of the cleaning solutions known in the art, such as a distilled water solution, a sulfuric acid solution, a hydrofluoric acid solution, among others. The method 100 may further include etching to form a pattern on the surface of the substrate before the step 110 using the same or different substrate processing system as in the method 100. One embodiment of the invention includes that these additional processes can be performed in the same substrate processing system in the method 100. Another embodiment of the invention includes additional substrate processing chambers and systems to perform one or more of these additional processes.

The first PVD chamber generally includes a first target which comprises the first metal material for sputtering the first metal material layer on the substrate and other target materials and components for structural support. Suitable first metal materials include, but are not limited to, molybdenum (Mo), molybdenum nitride (MoₓN_{y}), aluminum neodymium (AINd), aluminum nitride (AlₓN_{y}), titanium nitride (TiN), tantalum nitride (TaN), aluminum (Al), neodymium (Nd), tungsten (W), chromium (Cr), tantalum (Ta), titanium (Ti), copper (Cu), other metal nitrides, metal alloys, and combinations thereof. In one embodiment, the first metal material is molybdenum.

The second PVD chamber includes a second target comprising the second metal material for sputtering the second metal material layer. Suitable second metal materials include, but are not limited to, aluminum (Al), molybdenum (Mo), neodymium (Nd), aluminum neodymium (AINd), tungsten (W), chromium (Cr), tantalum (Ta), titanium (Ti), copper (Cu), aluminum nitride (AlₓN_{y}), molybdenum nitride (MoₓN_{y}), titanium nitride (TiN), tantalum nitride (TaN), other metal nitrides, metal alloys, and combinations thereof. In one embodiment, the second metal material is aluminum.

In one embodiment, the first PVD chamber and the second PVD chamber of the substrate processing systems of the invention are designated to process a three-layer deposition process where two thin layers of a first metal material is used to sandwich a thicker layer of a second metal material. In general, a thicker film/layer takes longer time to deposit. Accordingly, one or more substrates can be processed at a very high throughput to sequentially deposit a thin first material layer using the first PVD chamber, a thick second material layer using the second PVD chamber 412, and a thin third layer having the first material over the thick second material layer by transferring the substrate back to the first PVD chamber. Further, the throughput of the substrate processing systems for such a three-layer film stack can be improved to be at least about 25 substrates per hour, such as at least about 30 substrates per hour, using only two designated process chambers, and there is less idle time for the first PVD chamber and second PVD chamber.

In another embodiment, the first metal material layer may be used in a thin film transistor structure and may include one or more gate metal layers, conductor layers, or gate electrode layers to a thickness of about 50 Å to about 5000 Å. In another embodiment, the first metal material to be deposited on the substrate, thus, the first target material in the designated first PVD chamber, is chosen as a barrier material to prevent any chemical reaction between an underlying layer on the surface of the substrate and any subsequent material layers which may need to be deposited onto the substrate. As an example, a pure aluminum layer will tend to react to a substrate surface when silicon-containing materials are exposed on the substrate surface, and there is a need for a barrier layer, such as a molybdenum layer or other barrier materials, to be deposited on the substrate before and/or after the pure aluminum layer is deposited onto the substrate surface.

In another embodiment, the second metal material may be used as a gate metal layer, a conductor layer, or a gate electrode layer, to a thickness of about 50 Å to about 5000 Å. In still another embodiment, the second metal material is a different material than the first metal material. In a further embodiment, the second metal material is provided to enhance conductivity of a film stack containing the first and the second metal material layers. For example, a molybdenum layer can be deposited before or after an aluminum neodymium (AINd) layer on a substrate surface to increase the conductivity of a final film stack comprising molybdenum and aluminum neodymium since the conductivity of a single aluminum neodymium layer is not high enough for some applications.

In still another embodiment, one or more additional layers are deposited over the second metal material layer using a minimum of two designated PVD chambers. For example, the third metal material layer deposited over the second metal material layer can be served as a barrier layer and prevent the second metal material layer from reacting with any subsequent layers. As an example, a molybdenum layer can be deposited over an aluminum layer to reduce the chance of surface reaction with any subsequent silicon-containing material layer which may need to be deposited over the molybdenum and aluminum layers.

Accordingly, the film stack of the invention deposited using methods of the invention may include, but not limited to, a triple layer of molybdenum, aluminum, and molybdenum which are deposited using two or more designated PVD chambers; for example, the two or more targets in the two or more designated PVD chambers may each comprise an aluminum material or a molybdenum material for depositing the triple layer of molybdenum, aluminum, and molybdenum on the substrate. As another example, the film stack of the invention may be a triple layer of titanium, aluminum, and titanium, or a triple layer of titanium nitride, aluminum, and titanium nitride. Other example may include a layer of molybdenum underneath and a layer of aluminum neodymium over the molybdenum layer, or alternatively, a first layer of aluminum neodymium and a layer of molybdenum deposited over the aluminum neodymium layer. Further, a film stack containing copper and various barrier materials suitable for copper, such as a first layer comprising molybdenum, tantalum, or tantalum nitride, etc., a second layer comprising copper, and a third layer comprising copper barrier materials, can be deposited using the method and substrate processing system of the invention.

The film stack of the invention may be deposited on a substrate for fabricating a bottom gate thin film transistor (TFT) having a back channel etch (BCE) inverted staggered structure, or alternatively, a top gate thin film transistor. For example, the film stack of the invention may be deposited as a gate electrode layer having a thickness of about 5000 Å or less, such as from about 50 Å to about 4000 Å or from about 500 Å to about 3000 Å. As another example, the film stack of the invention may be deposited as a conductive layer or as a source/drain material layer having a thickness of about 7500 Åor less, such as from about 100 Å to about 6000 Å.

However, the thickness for the film stack of the invention is not limiting and may vary depending on the types of suitable metal materials and thus their material properties. For example, molybdenum can be deposited to a thickness of about 100 Å to about 3500 Å, such as a molybdenum layer having a thickness of about 100 Å to about 1500 Å, e.g., a molybdenum layer of about 500 Å or about 1000 Å, can be deposited before or after a different metal material layer. Further, the thicknesses of the first metal material layer and the third metal material layer having the same metal materials are not limiting and may be the same or different. In one embodiment, the thicknesses of the first metal material layer and the third metal material layer are thinner than the thickness of the second metal material layer, such that while the second metal material layer is deposited on one substrate using the second PVD chamber, the first PVD chamber can be used to deposit the first metal material layer and/or the third metal material layer on a previous substrate or a next substrate in a high throughput multi-substrate processing sequence. Since a thinner film takes less time to deposit, the three material layers with different thicknesses of thin-thick-thin or with different materials of first metal-second metal-first metal can be efficiently deposited in the two specific designated PVD chambers with convenient target configurations already and the substrate processing system can be kept at a very compact footprint.

According to one or more aspects of the invention, two or more designated PVD chambers are used to deposit the three metal material layers having varied thicknesses on the surface of a number of substrates for high throughput substrate processing, and there is no need to change the large dimension and heavy chamber lid, which generally includes the target, the magnetron (if electromagnetic scanning is used in conjunction with the target), and other components of the substrate processing system. The target, lid assembly, and related chamber components for PVD or sputtering are generally required to be somewhat larger than the substrate to provide uniform deposition across the whole surface of the substrate. Further, since the surface of the first metal material layer is immediately transferred to the second PVD chamber and kept in the vacuum environment of the same substrate processing system, air and other contaminants are unlikely to penetrate the surface of the substrate and there is no additional need for surface cleaning, such as using a hydrofluoric acid cleaning solution.

Generally, the throughput of a substrate processing system is represented by TACT time (Total Actual Cycle Time, the time period required for a substrate to be processed/cycled inside a tool, e.g., seconds/substrate) or enhanced numbers of substrates that a process tool can handled in a hour (no. of substrates/hour). Typically, depositing two different material layers on one or more substrates will affect the throughput at least two fold, e.g., half the throughput as compared to depositing a single layer on the one or more substrates. For example, a throughput of about 60 substrates per hour for a single layer deposition will be compromised at least three fold to, theoretically, less than 20 substrates per hour for a three-layer deposition.

It is observed that using methods and substrate processing systems of the invention, the throughput of processing a three-layered film stack is greatly enhanced to more than about 25 substrates per hour by optimizing substrate exchange during substrate transfer and scheduling various chambers in a specific order, such as the load lock chambers for loading, unloading, pre-processing heating, or post-processing cooling, and the first PVD and second PVD chambers adapted for processing at least three metal material layers. In addition, when two or more substrates are loaded sequentially inside a substrate processing system, the transfer robot is adapted to strictly follow a substrate exchange method, such as a method 500 (as described herein and shown in Figure) in a special timing sequence in order to move to these various chambers, obtain an unprocessed substrate, exchange the processed substrate with an unprocessed substrate, and transfer different substrates to different chambers. The timing of transferring the two or more substrates by the transfer robot among these various chambers is optimized, resulting in minimum process chamber requirement, maximized throughput for multi-substrate processing, and no apparent observed dead lock within substrate processing systems. In one embodiment, a high throughput of more than about 28 substrates per hour, such as more than about 30 substrates per hour, can be desirably obtained.

Examples of process chambers that may be adapted to benefit from the invention is a physical vapor deposition (PVD) process chamber, available from AKT, a division of Applied Materials, Inc., located in Santa Clara, Calif. Additional. PVD chambers that may be adapted to benefit from the invention are described in co-pending U.S. patent application Ser. Nos. 11/131,009 (docket number: AMAT/9566) filed on May 16, 2005, titled “Ground Shield for a PVD chamber” by Golubovsky; (docket number: AMAT/10169) titled “Integrated PVD System Using Designated PVD Chambers” by Hosokawa et al.; 11/167,377 (docket number: AMAT/10172) filed on Jun. 27, 2005, titled “Process Kit Design to Reduce Particle Generation” by Le et al.; 10/888,383 (docket number: AMAT/9309) filed on Jul. 9, 2004, titled “Staggered Target Titles” by Tepman; (docket number: AMAT/9661), filed on May 24, 2005, titled “Multiple Target Tiles with Complementary Beveled Edges Forming a Slanted Gap Therebetween” by Hosokawa et al.; 11/146,763 (docket number: AMAT/9729), filed on Jun. 6, 2005, titled “Bonding of Target Tile to Backing Plate with Patterned Bonding Agent” by Hosokawa et al.; (docket number: AMAT/10171) titled “Elastomer Bonding of Target Tiles” by Le et al.; and (docket number: AMAT/10170) filed on Jun. 13, 2005, titled “Electronic Beam Welding of Sputtering Target Tiles” by Hosokawa et al., all of which are hereby incorporated by reference in their entireties.

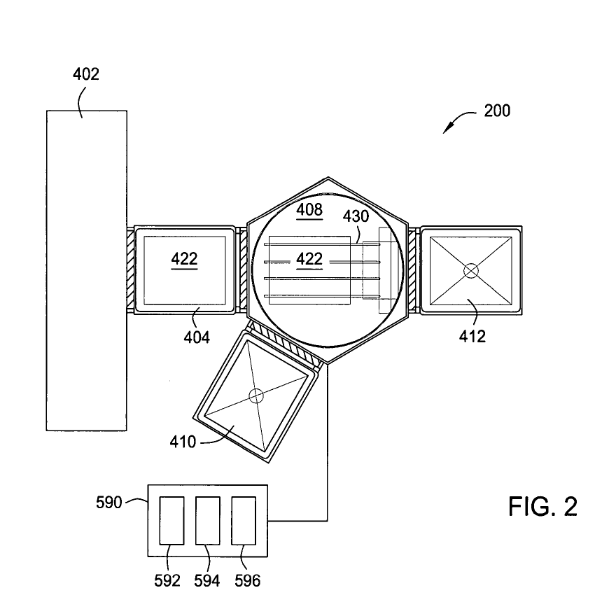

FIG. 2 is a plan view of an exemplary substrate processing system 200 with a minimum of two process chambers 410, 412, such as a PVD process chamber for sputtering multi-layers of metal films on a substrate 422, according to one or more embodiments of the invention. The substrate processing system 200 generally includes a transfer chamber 408 coupled to a load lock chamber 404. The transfer chamber 408 generally includes a transfer robot 430 for executing substrate transfer and substrate exchange in a timely order. The substrate processing system 200 may also include a controller 590 adapted to execute a software-controlled multi-substrate processing sequence.

The controller 590 is included to interface with and control various components of the substrate processing systems of the invention. The controller 590 typically includes a central processing unit (CPU) 594, support circuits 596 and a memory 592. The CPU 594 may be one of any form of computer processor that can be used in an industrial setting for controlling various chambers, apparatuses, and chamber peripherals. The memory 592, any software, or any computer-readable medium coupled to the CPU 594 may be one or more readily available memory devices, such as random access memory (RAM), read only memory (ROM), hard disk, CD, floppy disk, or any other form of digital storage, for local or remote for memory storage. The support circuits 596 are coupled to the CPU 594 for supporting the CPU 594 in a conventional manner. These circuits include cache, power supplies, clock circuits, input/output circuitry, subsystems, and the like.

The controller 590 may be used to control operation of the substrate processing system, including any transferring among the load lock chamber 404, the transfer chamber 408, process chambers (e.g., the first and second PVD chambers 410, 412), and deposition processes performed therein. The controller 590 is also used to control processing/deposition time performed by the process chambers, and the timing for the movements of the transfer robot 430, including, without limitation, rotating around various chambers, vertically moving up and down, and extending and retracting in and out of the load lock chamber, the transfer chamber, and the process chambers, etc. The controller 590 execute these movements and timing according to a scheme of a predetermined fabrication sequence for processing one or more substrates and depositing a multi-layer film stack thereon.

In one embodiment, the controller 590 of the invention is used to control movements of one or more substrates being processed concurrently within the substrate processing systems. Specifically, the control of substrate movement by various substrate transfer or loading mechanisms (e.g., transfer robot 430, the transfer chambers 408, the load lock chamber 404, etc.) and any software associated therewith are linked to the software required for controlling different process time and process conditions for the process chambers or PVD chambers of the invention.

In one aspect, the same software, as compared to prior art separate software or commands, is used to control the movement of various substrate support/transfer mechanisms, such as the transfer robot 430 and a substrate support positioned inside a process chamber, such that the movements of one or more substrate supports in one or more process chambers are engaged or coordinated when the substrate being processed is being transferred to the process chamber by the transfer robot from the previous substrate transfer mechanism, transfer chamber, load lock chamber.

The substrate processing system 200 may also include a factory interface 402. In one embodiment, the factory interface 402 is not needed and the substrate 422 can be directly loaded to and unloaded from the load lock chamber 404. The factory interface 402 generally includes one or more substrates stored therein or substrate storage cassettes removably disposed in a plurality of storage bays/compartments formed. The factory interface 402 may also include an factory interface robot, such as an atmospheric robot. The atmospheric robot is adapted to transfer one or more substrates between the one or more substrate storage cassettes and the load lock chamber 404. Typically, the factory interface 402 is maintained at or slightly above atmospheric pressure and the load lock chamber 404 is disposed to facilitate substrate transfer between a vacuum environment of the transfer chamber 408 and a generally ambient environment of the factory interface 402.

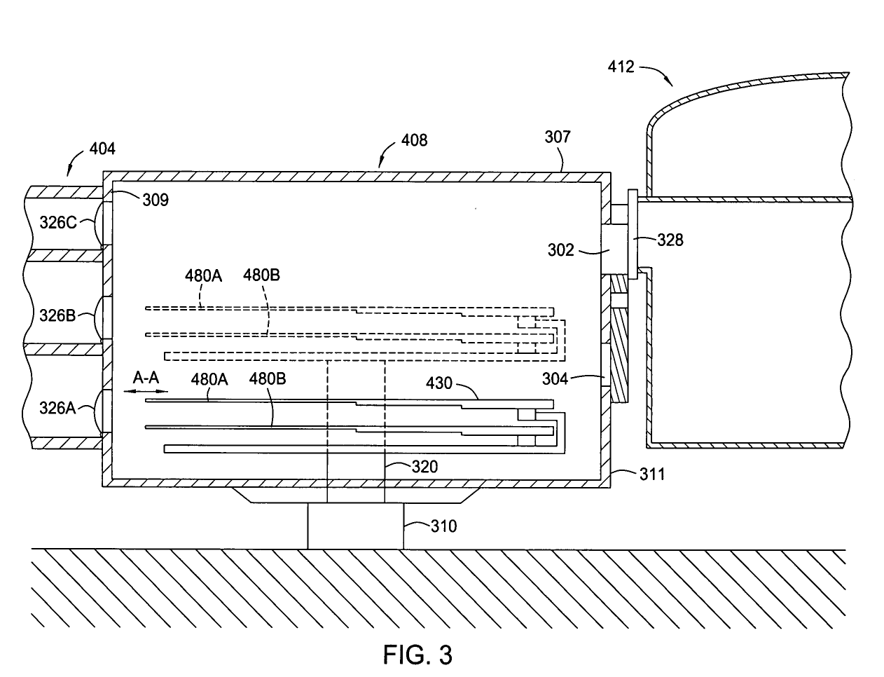

FIG. 3 is a sectional view of an exemplary configuration of the transfer chamber 408 according to one or more embodiments of the invention. The transfer robot 430, such as a dual arm vacuum robot available from Applied Materials, Inc., can be coupled to the transfer chamber 408 for moving the substrate 422. The transfer chamber 408 may be coupled to at least one process chamber, load lock chambers, buffer stations, substrate transfer shuttle chambers, and shuttle mechanisms, such as the process chambers 410, 412 and the load lock chamber 404, etc. The load lock chamber 404 may be, for example, a triple single substrate load lock (TSSL), a double dual slot load lock (DDSL), or other conventional load locks. The transfer chamber 408 is maintained at a vacuum condition to eliminate or minimize pressure differences between the transfer chamber 408 and the individual process chambers 410,412 after each substrate transfer.

The transfer chamber 408 generally includes a main body 307 configured to be positioned above a base 310. The main body 307 may have an interior wall 309 and an exterior wall 311. The shape of the interior wall 309 may be cylindrical in shape, or other shape, and the exterior wall 311 may be hexagonal or other shapes and may include flat regions which form side walls that are adapted to couple to the process chambers or load lock chambers of the invention. The main body 307 may be, for example, machined from a single piece of a material, such as stainless steel, aluminum, among others. The height of the main body 307 is minimized so as to reduce the overall volume and weight of the transfer chamber 408.

Each side wall of the transfer chamber 408 may include one or more openings coupled to one or more valves, such as slit valves 326A, 326B, 326C, through which the substrate 422 (not shown) may be transferred from the transfer chamber 408 to the load lock chamber 404, or vice versa, using the transfer robot 430. Other side wall may include one or more openings 302, 304. For example, the opening 302 may be coupled to a process chamber, for example, the process chamber 412 as shown in FIG. 3, via a valve 328. The valve 328 may be a conventional gate valve, a slit valve, or other conventional valves. The valve 326 may selectively open and close the opening 302 from the interior or exterior side of the side wall of the transfer chamber 408 using an actuator (not shown) mechanism (not shown) to pump down the pressure level of the transfer chamber 408 to a suitable degree of vacuum.

The pumping mechanism may include one or more pumps, such as a dry pump, a roughing pump, a turbo pump, and a cryogenic pump, among others, and the pressure of the transfer chamber 408 can be kept at a range of about 5 Torr or lower, such as a range of about 1 Torr or lower, or even about 10⁻³ Torr or less, depending on the required minimum pressure difference between the process chambers and the transfer chamber. One embodiment of the invention provides the transfer chamber being coupled to a cryogenic pump with high evacuation efficiency to obtain high vacuum base pressure of the transfer chamber compatible for the high vacuum requirement of a PVD process and the transfer chamber 408 can be kept at a base pressure of about 104 Torr or less, such as at about 10⁻⁵ Torr to about 10⁻⁶ Torr.

A shaft 320 and a lift mechanism may be coupled to the transfer robot 430 and the base 310 of the transfer chamber 408 to provide rotational movement and vertical movement of the transfer robot 430. The rotational movement of the transfer robot 430 may be required for moving the substrates 422 among the different chambers coupled to the transfer chamber 408 and the vertical movement of the transfer robot 430 may be required for moving the substrates 422 vertically to a position to be aligned to the different access ports and/or openings on the side walls of the various chambers of the invention.

The transfer robot 430 of the invention may include two or more robot blades 480A, 480B adapted to hold the substrate 422 thereon in order to facilitate the method 500 of transferring and exchanging multiple substrates in various chambers within the substrate processing systems of the invention. The robot blades 480A, 480B are adapted to move vertically and rotationally using the shaft 320, the lift mechanism and other mechanisms. In one embodiment, the robot blades 480A, 480B of the transfer robot 430 are configured to extend and retract in a linear direction A-A of a horizontal plane and move through valves and openings, such as the opening 302, the valve 326, and the slit valves 326A, 326B, 326C on the side walls of the transfer chamber 408 using actuators and motors coupled thereto in order to load and unload the substrates 422 to various chambers The use of two or more robot blades for the transfer robot as compared to robots with only on one blade provides a faster and convenient way for handling multiple substrates on both blades at the same times, instead of going back and forth for single substrate, resulting in higher reliability for the transfer robot. In addition, the robot blades can serve as a buffer station to temporally placing unprocessed and/or process substrates.

Additional transfer chambers that may be adapted to benefit from the invention are described in commonly assigned U.S. Pat. No. 6,786,935, filed Mar. 10, 2000, entitled “Vacuum Processing System for Producing Components”, by Powell; and U.S. patent application Ser. No. 10/601,185, filed Jun. 20, 2003, entitled “Transfer Chamber for Vacuum Processing System”, by Kurita et al., which are hereby incorporated by reference in their entireties.

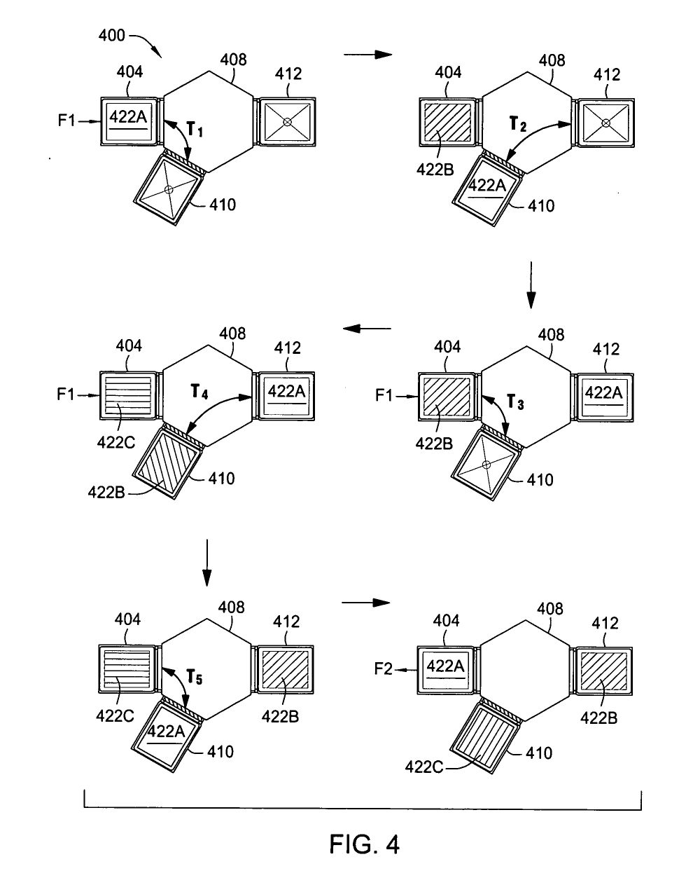

FIG. 4 is a flow chart of an exemplary method 400, illustrating the flow of multiple substrate that need to be transferred by the transfer robot 430 of the invention within the transfer chamber 408 of the substrate processing system having a minimum of two process chambers 410, 412 and one load lock chamber 404. According to one or more embodiments of the invention, the transfer robot 430 generally follow a plurality of transfer robot paths T1, T2, T3, T4, T5 adapted to transfer a plurality of substrates. Each of the transfer robot paths represents the exchange of the substrates located between the two chambers that are indicated by the respective arrows of the transfer robot paths T1, T2, T3, T4, T5.

As shown in FIG. 4, a first substrate 422A may be loaded into the load lock chamber 404, such as via a factory interface robot path, F1. Then, the controller 590 may execute the transfer robot path T1 such that the first substrate 422A is transferred and exchanged from the load lock chamber 404 to the process chamber 410 in order to deposit a first material layer on the first substrate 422A.

The transfer robot path T2 is then followed to transfer and exchange the first substrate 422A from the process chamber 410 to the process chamber 412 in order to deposit a second material layer on the first substrate 422A. While the first substrate 422A is being processed, the transfer robot 430 may need to follow the transfer robot path T3 to transfer and exchange a second substrate 422B from the load lock chamber 404 to the process chamber 410 in order to deposit a first material layer on the second substrate 422B.

The transfer robot path T4 is advantageously configured such that the transfer robot 430 can transfer and exchange the first substrate 422A and the second substrate 422B after substrate processing is finished in the process chambers 410 and 412 and in-situ deposition of additional material layers on the first substrate 422A and the second substrate 422B is conveniently performed. For example, a third material layer can be deposited on the first substrate 422A in process chamber 410 and, concurrently, a second material layer can be deposited on the second substrate 422B in process chamber 412 without affecting the throughput of the substrate processing system. In another word, a three-layer deposition sequence of the invention can be optimized to have a much higher throughput than any prior art designs and may include a high throughput comparable to a throughput for a two-layer deposition sequence.

The transfer robot 430 may then follow the transfer robot path T5 after the third material layer is deposited on the first substrate 422A in order to transfer and exchange the first substrate 422A and a third substrate 422C between the process chambers 410 and the load lock chamber 404. The first substrate 422A can then be unloaded directed or through a factory interface robot path, F2.

One distinctive feature of the method 400 is that at least one of the process chamber, such as the process chamber 410, of the substrate processing system of the invention is required to constantly exchange substrates with another chambers. In one embodiment, each of the transfer robot paths T1, T2, T3, T4, T5 includes substrate exchange for the process chamber designated to deposit the first and the third material layers. In another embodiment, the process chamber 410 is conveniently located close to the load lock chamber, such as between the load lock chamber 404 and the process chamber 412.

One embodiment of the invention provides that each of the transfer robot paths T1, T2, T3, T4, T5 includes essentially the same robot movement in order to exchange of the substrates between two chambers. For example, the movement of the transfer robot having the robot blades 480A, 480B may include obtaining one substrate from a chamber using one robot blade and placing another substrate from the same chamber using another robot blade.

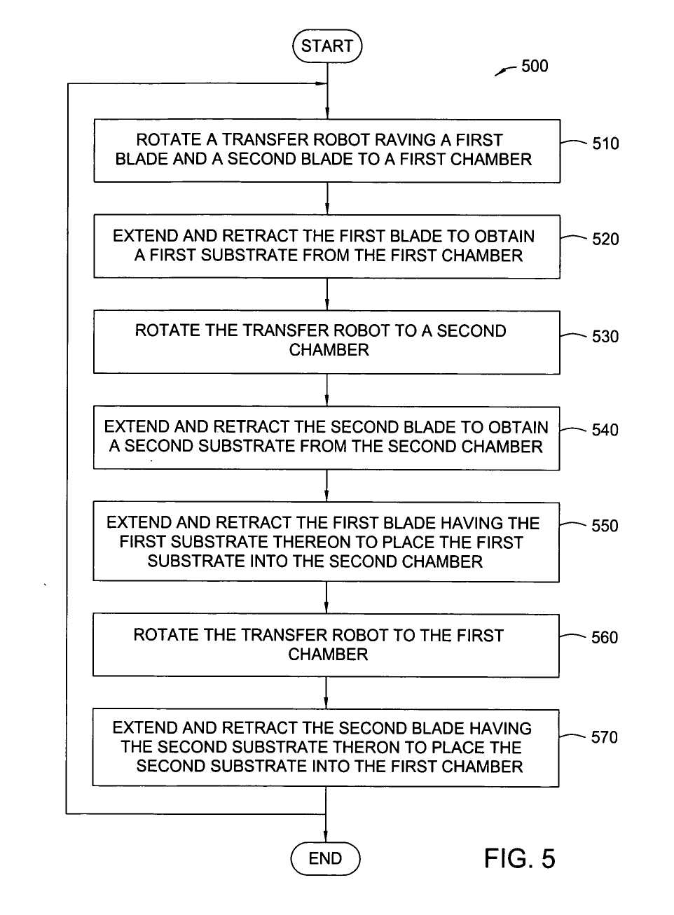

FIG. 5 illustrates a flow chart of an exemplary method 500, illustrating in detail various steps required for the movement of the transfer robot 430 in order to perform substrate exchange, e.g., exchanging two substrates between two chambers. The method 500 can be configured to execute each of the transfer robot paths T1, T2, T3, T4, T5, and/or substrate transfer steps of the invention, such as the transfer steps of the method 100, the steps 120, 140, 160, 180, as described in FIG. 1.

Firstly, a transfer robot having at least a first blade and a second blade, each adapted to hold a substrate thereon, is provided. At step 510, the transfer robot is configured to rotate to a first chamber. At step 520, the first blade is configured to extend and retract in order to obtain a first substrate form the first chamber. At step 530, the transfer robot is configured to rotate to a second chamber and, at step 540, the second blade is configured to extend and retract in order to obtain a second substrate form the second chamber.

At step 550, without the need to rotating the transfer robot, the first blade holding the first substrate thereon is configured to extend and retract in order to place the first substrate form the second chamber. Additional steps may be required for the vertically movement of transfer robot in order to align the first blade and/or the second blade to desired openings on the side walls of the transfer chamber for extending in and out of various process chambers or load lock chambers. At step 560, the transfer robot is configured to transfer back to the first chamber, and at step 570, the second blade having the second substrate thereon is configured to extend and retract in order to place the second substrate into the first chamber.

In one embodiment, the transfer robot having at least two or more blades is configured to obtain two or more substrates from various chambers before placing the substrates into the chambers. In another embodiment, the use of two or more blades enables the transfer robot to exchange substrates for a desired chamber without taking extra time to rotate the transfer robot, for example, obtaining a substrate from a chamber and placing another substrate to the same chamber, thereby reducing the number of moves for the transfer robot.

In a special embodiment, the second chamber as described at step 540 and step 550 of the method 500 is the process chamber 410 of the invention designated to deposit the first and the third material layers. Thus, the first chamber as described in the method 500 may be a load lock chamber or other process chamber, such as the load lock chamber 404 and the process chamber 412 as shown in FIG. 4. Accordingly, one embodiment of the invention provides configuring the controller 590 to execute the movements of the transfer robot 430 according to the method 500 such that at least one of the process chamber designated for depositing the first and the third material layers is constantly exchanging substrates with other chambers. One example of the high throughput substrate movement and process chamber scheduling involves that the transfer robot is adapted to obtain a first substrate from other chambers, exchange the first substrate with a second substrate in the designated process chamber, and then place the second substrate to the other chambers.

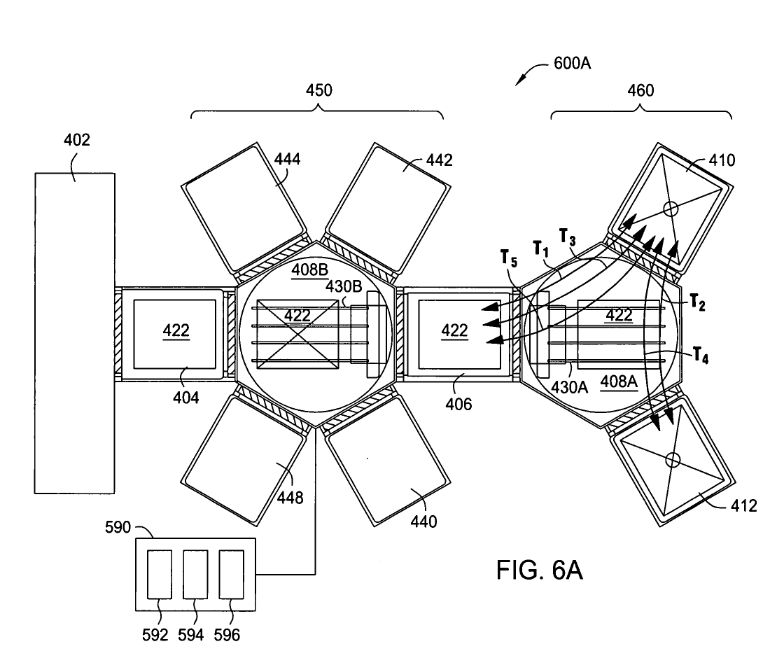

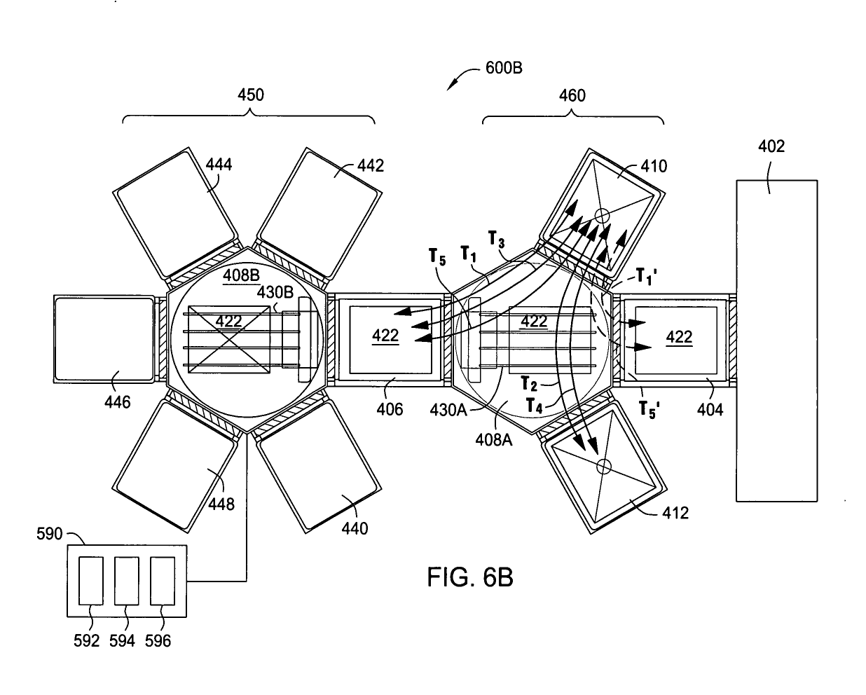

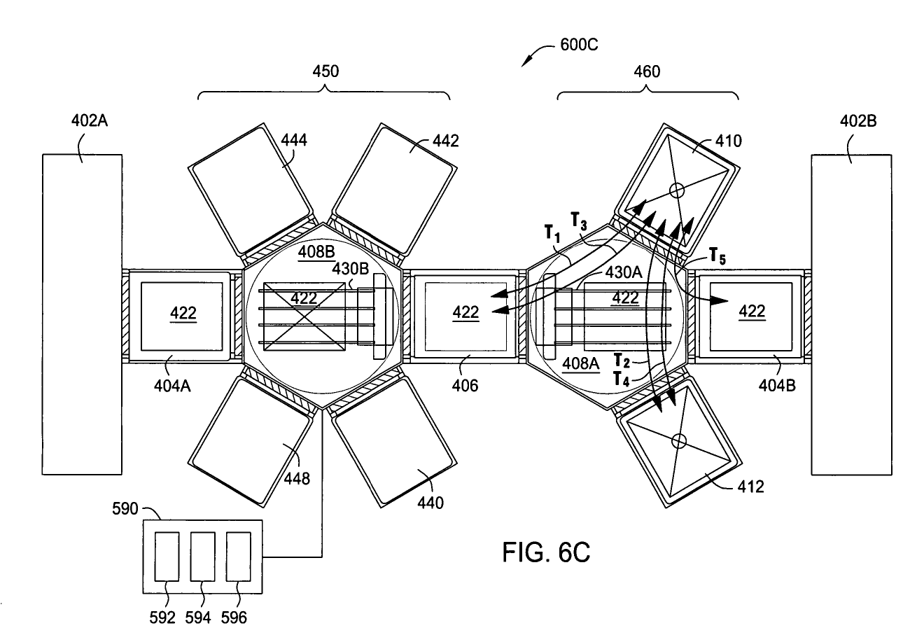

FIGS. 6A-6C are plan views of exemplary substrate processing systems 600A, 600B, 600C suitable for depositing a multi-layered film stack on a substrate 422 according to embodiments of the invention. The substrate processing systems 600A, 600B, 600C may generally include two process modules 450 and 460 coupled together via a load lock chamber 406. As shown in FIGS. 6A-6C, the transfer robot is configured to constantly exchange substrates between the process chamber 410 and various other chambers.

The process module 460 may include the process chambers 410, 412 coupled to a transfer chamber 408A having a transfer robot 430A. In one embodiment, the transfer robot 430A may follow the transfer robot paths T1, T2, T3, T4, T5 for high throughput multi-substrate processing.

The process module 450 may include a plurality of process chambers 440, 442, 444, 446, 448 coupled to a transfer chamber 408B having a transfer robot 430B therein. In one embodiment, the process chambers 440, 442, 444, 446, 448 in the process module 450 are configured to include a different type process chamber than the process chamber 410, 412 in the process module 460. In another embodiment, at least one of the process chambers 440, 442, 444, 446, 448 is a CVD chamber, such as those available from Applied Materials, Inc. Preferably, the CVD chamber is configured for depositing a silicon-containing material on the substrate 422.

The factory interface 402 can be coupled to the substrate processing systems 600A, 600B via the load lock chamber 404 which may be coupled to the process module 450 or process module 460, respectively. In FIG. 6B, tow alternative transfer robot paths T1 or T1′ is shown since the substrate 422 may first be processed by the process module 450 or the process module 460. After going through the transfer robot paths T1 (or T1′), T2, T3, T4, the substrate may be transferred to a different process module or unloaded form the substrate processing system through the factory interface 402. For example, the transfer robot path T5 is configured between the process chamber 410 and the load lock chamber 406, as shown in FIG. 6B. Alternatively, the transfer robot path T5′ can be configured between the process chamber 410 and the load lock chamber 404.

In some cases, two factory interface 402A, 402B are configured to facilitate flow through of the substrate being processed and provide hardware flexibility. As shown in FIG. 6C, the substrate 422 can be loaded to the substrate processing system 600C via either the factory interface 402A or the factory interface 402B and exited the substrate processing system 600C flexibly using either the factory interface 402A or 402B. In FIG. 6C, only one example of the suitable transfer robot paths T1, T2, T3, T4, T5 is shown, illustrating one exemplary configuration of flowing the substrate 422 from the factory interface 402A through the load lock chamber 406 and out of the substrate processing system 600C via the factory interface 402B. In this example, it is clear that the transfer robot 430A is configured to constantly exchange substrates between the process chamber 410 and various other chambers.

The load lock chambers 404, 404A, 404B provide a good buffer station for flowing the substrate 422 from the atmospheric environment of the factory interface 402 to the high vacuum level of the transfer chamber 408 in a specific manner as may be needed during an in-situ integrated fabrication sequence to deposit a multi-layer film stack on the substrate 422. The load lock chambers 404 is adapted with suitable pumping mechanisms to obtain a desired vacuum level before a substrate is transferred to the transfer chamber and also includes suitable venting mechanisms to reach a desired pressure level before a unprocessed substrate is loaded therein. The load lock chambers 404 may also be used to perform additional substrate preparation or treatment steps on the substrate 422, such as heating, cooling, among others. In one embodiment, the load lock chamber 404 may include one or more load lock slots designated for pre-processing heating and post-processing cooling.

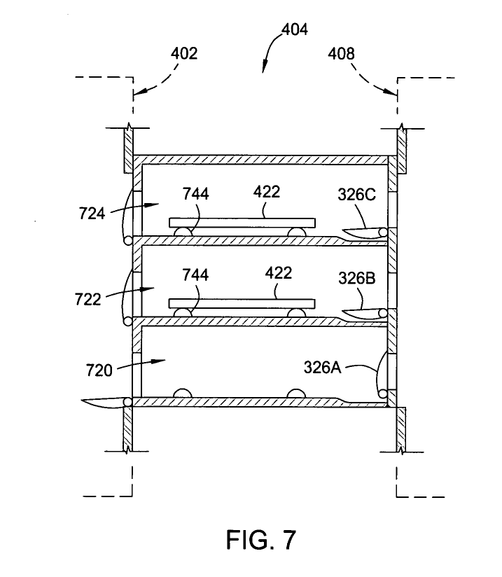

FIG. 7 illustrates one exemplary load lock chamber 404 having three load lock slots 720, 722, 724. At least one of the load lock slots 720, 722, 724 of the load lock chamber 404 is adapted to rapidly heat and cool the substrate 422 when positioned on a substrate support 744 inside the load lock chamber 404. For example, the substrate 422 to be processed may be pre-heated to a temperature of about 80° C. or more, or close to a desired process temperature for the process chambers, such as about 100° C. or more, such that the substrate 422 can be loaded onto the process chambers to be processed immediately. As another example, the substrate 422 can be pre-heated inside the load lock chamber 404 to about 120° C. for a processing temperature of between about 100° C. to about 120° C. inside the process chambers 410, 412. Accordingly, there is no waiting for the temperature of the process chambers to be reached to the desired temperature, especially when two or more designated process chambers are used for a substrate processing sequence, and the substrate processing throughput can be improved dramatically.

Detail of the heating and cooling capability of the load lock chamber 404 is described in commonly assigned U.S. Pat. Nos. 6,086,362; 6,193,507; and 6,435,868, titled “Multi-Function Chamber for a Substrate Processing System; and in co-pending U.S. patent applications (docket number: AMAT/10200) titled “Load Lock Chamber with Substrate Temperature Regulation” by Hosokawa et al.; and docket number: AMAT/10201) titled “Method and Apparatus for Substrate Temperature Control Utilizing Gas Delivered” by Le et al., all of which are incorporated by reference in their entirety.

Another embodiment of the invention provides that at least one of the load lock slots 720, 722, 724 of the load lock chamber 404 is adapted to pre-heat the substrate 422 before loading into the process chambers 410, 412, 414, 418, 420 and there is no separate pre-heat chamber to be coupled to the substrate processing systems of the invention. In addition, at least one of the load lock slots 720, 722, 724 is designated to cool the substrate 422 after substrate processing. In one configuration, one of the load lock slots 720, 722, 724 is designated for substrate pre-heating and two of the load lock slots 720, 722, 724 are designated for substrate cooling since timing is essence and cooling a substrate may takes longer than heating a substrate. For example, the substrate processing system of the invention may include a load lock slot 720 adapted to pre-heat a substrate therein and two load lock slots 722, 724 adapted to cool the substrate therein after substrate processing since cooling of the substrate may take longer, such that the throughput of the substrate processing system is improved.

In one embodiment, the substrate processing systems of the invention are adapted to process a rectangular substrate. The surface area of a rectangular substrate for flat panel display is typically large, for example, a rectangle of about one square meter or larger, such as at least about 370 mm by about 470 mm. For flat panel display application, the substrate may comprise a material that is essentially optically transparent in the visible spectrum, for example glass or clear plastic. However, the invention is equally applicable to substrate processing of any types and sizes. Substrates of the invention can be circular, square, rectangular, or polygonal for flat panel display manufacturing. In addition, the invention applies to substrates for fabricating any devices, such as flat panel display (FPD), flexible display, organic light emitting diode (OLED) displays, flexible organic light emitting diode (FOLED) display, polymer light emitting diode (PLED) display, liquid crystal displays (LCD), organic thin film transistor, active matrix, passive matrix, top emission device, bottom emission device, solar cell, solar panel, etc., and can be on any of the silicon wafers, glass substrates, metal substrates, plastic films (e.g., polyethylene terephthalate (PET), polyethylene naphthalate (PEN), etc.), plastic epoxy films, among others.

According to one or more aspects of the invention, substrate transfer and substrate exchange using the transfer robot 430, 430A is required to follow the commands from the controller 590, which is configured to stored various software and commands and integrate the steps as described in the method 100, 400, and 500 for processing multiple substrates. On example of a three-layer deposition process on one or more substrates using methods and substrate processing systems of the invention is described in detail below. A PVD cluster tool available from Applied Materials, Inc. is configured to a first molybdenum layer, a second aluminum layer, and a third molybdenum layer on each substrate.

The first molybdenum layer is deposited using a first PVD chamber having a molybdenum-containing target for about 30 seconds or more at a high deposition rate of about 2200 Å/min or larger to include a thickness of about 750 Å or larger. The second aluminum layer is deposited using a second PVD chamber having a aluminum-containing target for about 50 seconds or more at a high deposition rate of about 3000 Å/min or larger to include a thickness of about 2500 Å or larger. The third molybdenum layer is deposited using the same first PVD chamber for the first molybdenum layer for about 20 seconds or more at a high deposition rate of about 2000 Å/min or larger to include a thickness of about 500 Å or larger.

Each substrate is transferred from a load lock slot adapted to pre-heat the substrate, through the first PVD chamber, the second PVD chamber, and back to the first PVD chamber before transferring to a different load lock slot adapted to cool the substrate before exiting the PVD cluster tool. After optimized transfer robot movement and process chamber scheduling, a high throughput of about 29.27 substrates per hour using the PVD cluster tool can be desirably obtained.

While the foregoing is directed to embodiments of the present invention, other and further embodiments of the invention may be devised without departing from the basic scope thereof, and the scope thereof is determined by the claims that follow.

1. A method of transferring one or more substrates in a substrate processing system having at least one load lock chamber, at least one first process chamber, and at least one second process chamber, comprising:
providing the one or more substrates to the at least one load lock chamber, the at least one first process chamber, and the at least one second process chamber in the substrate processing system;
exchanging the one or more substrates between the at least one load lock chamber and the at least one first process chamber to deposit a first material layer on the one or more substrates;
exchanging the one or more substrates between the at least one first process chamber and the at least one second process chamber to deposit a second material layer on the one or more substrates;
exchanging the one or more substrates between the at least one load lock chamber and the at least one first process chamber;
exchanging the one or more substrates between the at least one second process chamber and the at least one first process chamber to deposit a third material layer comprising the same material as the first material layer on the one or more substrates;
exchanging the one or more substrates between the at least one first process chamber and the at least one load lock chamber; and
unloading the one or more substrates from the substrate processing system.

2. The method of claim 1, wherein each of the exchanging steps comprises obtaining a substrate from the at least one first process chamber and placing another substrate into the at least one first process chamber.

3. The method of claim 1, wherein the one or more substrates comprises large area rectangular substrates of about one square meter or larger.

4. The method of claim 1, wherein the first material layer and the third material layer comprises molybdenum and the second material layer comprises aluminum.

5. The method of claim 1, wherein the throughput of the substrate processing system adapted to transfer and process the one or more substrates is about 28 substrates per hour or more.

6. A method of processing a film stack having a first material layer, a second material layer, and a third material layer over one or more substrates in a substrate processing system, comprising:
providing the one or more substrates to the substrate processing system having at least one load lock chamber, at least one first process chamber, and at least one second process chamber;
configuring the at least one first process chamber to deposit the first material layer and the third material layer on the one or more substrates;
configuring the at least one second process chamber to deposit the second material layer on the one or more substrates; and
exchanging the one or more substrates between the at least one first process chamber and other chambers, including the at least one load lock chamber and the at least one second process chamber.

7. The method of claim 6, wherein the exchanging step comprises obtaining a substrate from the at least one first process chamber and placing another substrate into the at least one first process chamber.

8. The method of claim 6, wherein the exchanging step comprises:
rotating a transfer robot of the substrate processing system to the other chambers, the transfer robot having at least a first blade and a second blade;
extending and retracting the first blade of the transfer robot to obtain a first substrate from the other chambers;
rotating the transfer robot to the at least one first process chamber;
extending and retracting the second blade of the transfer robot to obtain a second substrate from the at least one first process chamber;
extending and retracting the first blade having the first substrate to place the first substrate into the at least one first process chamber;
rotating the transfer robot to the other chambers; and
extending and retracting the second blade having the second substrate to place the second substrate into the other chambers.

9. The method of claim 6, wherein the one or more substrates comprises large area rectangular substrates of about one square meter or larger.

10. The method of claim 6, wherein the first material layer and the third material layer comprises molybdenum and the second material layer comprises aluminum.

11. The method of claim 6, wherein the throughput of the substrate processing system adapted to transfer and process the one or more substrates is about 28 substrates per hour or more.

12. A method of transferring substrates in a substrate processing system having at least one load lock chamber, at least one first process chamber, and at least one second process chamber, comprising:
loading a first substrate to the at least one load lock chamber of the substrate processing system;
transferring the first substrate from the at least one load lock chamber to the at least one first process chamber to deposit a first material layer on the one or more substrates;
transferring the first substrate from the at least one first process chamber to the at least one second process chamber to deposit a second material layer on the first substrate;
providing a second substrate to the at least one load lock chamber of the substrate processing system;
transferring a second substrate from the at least one load lock chamber to the at least one first process chamber;
transferring the first substrate from the at least one second process chamber back into the at least one first process chamber to deposit a third material layer comprising the same material as the first material layer on the first substrate; and
transferring the first substrate from the at least one first process chamber to the at least one load lock chamber; and
unloading the first substrate from the at least one load lock chamber of the substrate processing system.

13. The method of claim 12, wherein the first material layer and the third material layer comprises molybdenum and the second material layer comprises aluminum.

14. The method of claim 12, wherein the throughput of the substrate processing system adapted to transfer and process the first and the second substrates is about 28 substrates per hour or more.

15. The method of claim 12, wherein the at least one load lock chamber is adapted to pre-heat and cool the first and the second substrates.

16. The method of claim 12, wherein the at least one load lock chamber comprises two or more load lock slots and different load lock slots are configured for the loading and unloading steps.

17. A computer readable medium containing instructions in a program which, when executed, performs an operation for transferring one or more substrates in a substrate processing system having at least one load lock chamber, at least one first process chamber, and at least one second process chamber, the operation comprising:
providing the one or more substrates to the at least one load lock chamber, the at least one first process chamber, and the at least one second process chamber in the substrate processing system; configuring the at least one first process chamber to deposit a first material layer and a third material layer on the one or more substrates;
configuring the at least one second process chamber to deposit a second material layer on the one or more substrates; and
exchanging the one or more substrates between the at least one first process chamber and other chambers, including the at least one load lock chamber and the at least one second process chamber.

18. The computer readable medium of claim 17, wherein the computer readable medium and the instructions are embodied in a memory, which is coupled to a controller of the substrate processing system.

19. The computer readable medium of claim 17, wherein the operation further comprises:
exchanging the one or more substrates between the at least one load lock chamber and the at least one first process chamber to deposit the first material layer on the one or more substrates;
exchanging the one or more substrates between the at least one first process chamber and the at least one second process chamber to deposit the second material layer on the one or more substrates;
exchanging the one or more substrates between the at least one load lock chamber and the at least one first process chamber;
exchanging the one or more substrates between the at least one second process chamber and the at least one first process chamber to deposit the third material layer comprising the same material as the first material layer on the one or more substrates; and
exchanging the one or more substrates between the at least one first process chamber and the at least one load lock chamber.

20. The computer readable medium of claim 17, wherein a transfer robot having at least a first blade and a second blade is coupled to the substrate processing system and the operation further comprises:
rotating the transfer robot of the substrate processing system to the other chambers;
extending and retracting the first blade of the transfer robot to obtain a first substrate from the other chambers;
rotating the transfer robot to the at least one first process chamber;
extending and retracting the second blade of the transfer robot to obtain a second substrate from the at least one first process chamber;
extending and retracting the first blade having the first substrate to place the first substrate into the at least one first process chamber;
rotating the transfer robot to the other chambers; and
extending and retracting the second blade having the second substrate to place the second substrate into the other chambers.
